(19) United States
(12) Patent Application Publication
(10) Pub. No.: US 2019/0182963 A1
(43) Pub. Date: Jun. 13, 2019

(54) METHOD FOR PRODUCING AN ELECTRIC COMPONENT CARRIER FOR AUTOMOBILE APPLICATIONS

(71) Applicant: Kiekert AG, Heligenhaus (DE)

(72) Inventor: Andreas Schmitz, Velbert (DE)

(73) Assignee: Kiekert AG, Heligenhaus (DE)

(21) Appl. No.: 16/310,984

(22) PCT Filed: May 19, 2017
(86) PCT No.: PCT/DE2017/100434

§ 371 Date: Dec. 18, 2018

(30) Foreign Application Priority Data
Jul. 4, 2016 (DE) 10 2016 112 181.9

(51) Int. Cl. H05K 3/20; H05K 1/02; H05K 3/28; H05K 3/00

(52) U.S. Cl. CPC H05K 3/202; H05K 1/0292; H05K 3/284; H05K 3/0014; E05B 81/54; H05K 2203/1476; H05K 2203/1305; H05K 2203/033; H05K 2203/175

(57) ABSTRACT

A method for producing an electric component carrier for automobile applications, in particular an electric component carrier for a lock. The electric component carrier is equipped with a conductive track arrangement and a base plate, which supports the conductive track. In the initial state, the conductive track arrangement has one or more separation points depending upon the required mode of operation in the operational state. According to the invention, the conductive track arrangement in the initial state is coated at least partially with a casting compound by means of injection molding and then the separation point is introduced into the free region.

The invention relates to a method for producing an electric component carrier for automobile applications, in particular an electric component carrier for a lock. The electric component carrier is equipped with a conductive track arrangement and a base plate, which supports the conductive track. In the initial state, the conductive track arrangement has one or more separation points depending upon the required mode of operation in the operational state.

Electric component carriers are usually used to bond electrical/electronic components and for example to control mechanical elements of a motor vehicle door lock, and query them by means of sensors, etc. In this case, the electric component carrier is an integral part of a lock housing of a motor vehicle door lock, i.e. an electric component carrier for a lock. The electric component carrier in question is generally produced so as to be able to equip the conductive track arrangement with the electrical/electronic components and then for example connect to a supporting element as the base plate, which supports the conductive track. To complete the process, the relevant electric component carrier is usually coated with a casting compound to protect the electrical/electronic components and conductive track arrangement from dirt or damage. This basic procedure is for example described in DE 20 2012 105 073 U1 of the applicant.

In the class-specific state of the art according to WO 2012/171596 A1, a divisible conductive track arrangement is used for a motor vehicle equipment part that has one or more separation points. Parts of the conductive track arrangement are connected to one another in the initial state via the separation points.

After introducing one or more separation points into the conductive track arrangement in the initial state, there is the possibility to adapt the relevant conductive track arrangement and consequently the electric component carrier overall to the respectively required mode of operation. This means that the relevant conductive track arrangement in the initial state is configured and designed in such a way that different variants of the electric component carrier can hereby be executed in the operational state. To this end, the conductive track arrangement is equipped with the respective separation points depending upon the required mode of operation.

The well known procedure has proven itself in this respect in that warehousing is simpler and price benefits are evident at the procurement stage for such conductive track arrangements. However, the introduction of the separation points into the conductive track arrangement is not without problems and is also not explained in greater details within the scope of the known theory. In fact, such conductive track arrangements are usually configured as so-called leadframes, and are consequently stamped out of a metal plate or metal film. Due to the low material thickness of the individual conductors or conductor strips of the conductive track arrangement, when subsequently introducing the separation points, there is the risk of the whole conductive track arrangement becoming bent or essentially even damaged. The invention intends to provide an overall remedy here.

The invention is based on the technical problem of specifying such a method for producing an electric component carrier for automobile applications and in particular an electric component carrier for a lock, with the aid of which the introduction of separation points succeeds in a damage-free and cost-effective manner.

In order to solve this technical issue, a class-specific method for producing an electric component carrier within the scope of the invention is characterized in that the conductive track arrangement in the initial state is at least partially coated with a casting compound and that the separation point is then introduced into the free region.

For a start, with a procedure like this, the invention assumes that by at least partially coating the conductive track arrangement with the casting compound, the conductive track arrangement is essentially stabilized so that the introduction of the separation point is executed in a problem-free and damage-free manner. The free region in this context is characterized in that the conductive track arrangement is still free in this region and has not been coated with the casting compound. Usually one or more of the separation points are restricted to a very limited region of the conductive track arrangement so that the casting compounds extensively encompass the conductive track arrangement and can take it itself.

Thus, the conductive track arrangement is on the one hand protected by the casting compound through the subsequent introduction of the separation point into the free region and on the other hand, the casting compound ensures that the conductive track arrangement equipped therewith is stabilized to such an extent that one or more separation points can be introduced into the remaining free region in a problem-free and damage-free manner. This means that due to the stabilization resulting from the casting compound, there is no risk (no longer a risk) within the scope of the invention, of the conductive track arrangement becoming bent or damaged in any way when the separation point is introduced.

In fact, in this context it has proven especially beneficial if the respective separation point is generally introduced into the conductive track arrangement using a stamping/bending process. In this context, the regular and beneficial procedure is that the respective separation point is stamped free. Within the scope of the invention, this means a stamping process that ensures that the respective conductor or conductor strip of the conductive track arrangement in the region of the separation point is completely cut through with the aid of the stamping tool.

The invention is typically based on the insight that the relevant conductor of the conductive track arrangement is ultimately a flat conductor strip of a specified width. The material thickness of this conductor strip corresponds to the material thickness of the sheet metal or metal film, out of which the conductive track arrangement is stamped in the initial state.

Where several separation points are defined in the respective conductive track arrangement, it is also possible to work with several stamps in the relevant stamping tool, to which appropriate openings correspond. In this context, it has also proven beneficial, depending on the required mode of operation in the finished operational state of the electric component carrier, to select and control one or more stamps or stamp fingers of the stamping tool. The stamping process can therefore be adapted with ease to the relevant and desired mode of operation. To this end, with the aid of individual stamps or stamp fingers, a stamping configuration is selected that essentially takes into account the position of the individual separation points for the desired mode of operation on the conductive track arrangement. It is therefore comprehensible that the die is equipped with a maximum number of suitable openings, namely for when all stamps or stamp fingers of the stamping tool are used.

The conductive track arrangement that is thus partially coated and equipped with one or more separation points is then finally connected to the base plate. The partially coated conductive track arrangement that has at least one separation point hereby acts as a preliminary molding so to speak. This preliminary molding, preferably with simultaneous definition of the base plate, is fully coated with the casting compound, in other words, is completely coated by the casting compound. It is therefore comprehensible in all these cases that the conductive track arrangement is equipped respectively with the required electrical/electronic constructional elements, both prior to the partial coating process and also prior to the full coating, so that together with the conductive track arrangement they are protected by the covering of the casting compound.

The casting compound is generally plastic or a thermoplastic plastic, so that both the partial coating process and the full coating process respectively take place and are executed in one injection molding tool. In fact, the invention generally proceeds in such a way that the conductive track arrangement is initially partially coated in a first injection molding tool and then finally fully coated in another second injection molding tool. In principle, the partial coating process and the full coating process can be undertaken and executed in one and the same injection molding tool. Generally though, the first injection molding tool is used for the partial coating process and the second injection molding tool for the full coating or complete coating process. In essence, this can be attributed to the fact that after the partial coating, the stamping process to introduce one or more separation points is notoriously an interim matter so that the described injection processes in any case do not connect to one another either temporally or spatially.

Furthermore, it has been proven if the conductive track arrangement, depending on the mode of operation, is equipped with at least one contact connector in addition to the separation point, that has been introduced into an opening to connect switching means for example. This means the operation mode dependent equipping and adaptation of the conductive track arrangement in the initial state includes, according to the invention, not only the introduction of one or more separation points, but possibly also the attachment or introduction of one or more contact connectors.

This means that the conductive track arrangement is usually initially equipped with the electrical/electronic constructional elements. The conductive track arrangement prepared as such is then finally coated. Following this partial coating, the relevant partially coated conductive track arrangement is then equipped in the free region with one or several separation points. One or more contact connectors are introduced if necessary. Furthermore, additional electric/electronic constructional elements can be arranged if necessary in the free region during this process step. Finally, the conductive track arrangement equipped as such is then fully coated. With this full coating process with the casting compound and beneficially with plastic, the typical and additional procedure is that not only the conductive track arrangement with the attached electric/electronic constructional elements and if necessary the contact connector is tightly covered. But during the course of the full coating, the base plate, which supports the conductive track arrangement is generally also defined. For the base plate is usually designed as a plastic injection-molded component so that the production of the base plate and the full coating process for the conductive track arrangement can be completed in one operation.

When it comes to the base plate, this can essentially be a carrier plate or a supporting element, with the aid of which the electric component carrier is secured and placed into for example a lock housing of a motor vehicle door lock. In principle, the relevant base plate can also be designed as a component of the relevant lock housing.

The object of the invention is also an electric component carrier, as described in Claim 10. The relevant electric component carrier is beneficially produced with recourse to the previously described process. As a result, a process and an electric component carrier produced herewith are provided that is characterized on the one hand by few operational steps and consequently a cost-effective design, and on the other hand, a damage-free procedure. The invention initially supposes the realization that all variants and consequently all modes of operation can be executed in the finished operational state of the electric component carrier, starting from a (single) conductive track arrangement in the initial state. Thus, all conceivable modes of operation of the electric component carrier can be covered by this one single conductive track arrangement. For example, it is conceivable to implement a semi-electric or fully electric variant for the electric component carrier for a lock.

Depending on the desired variant and consequently the mode of operation in the operational state achieved following production, the conductive track arrangement in question is then prepared accordingly. One or more separation points are introduced for this. As are the optional contact connectors. Since one or more separation points can usually be defined at the same time by a stamping process, the adaptation to the desired mode of operation is quick and focused since the invention works with the already partially coated conductive track arrangement for the described stamping process, and the conductive track arrangement is hereby not damaged. These are the fundamental advantages.

Hereinafter, the invention is explained in further detail on the basis of a drawing which only depicts an execution example.

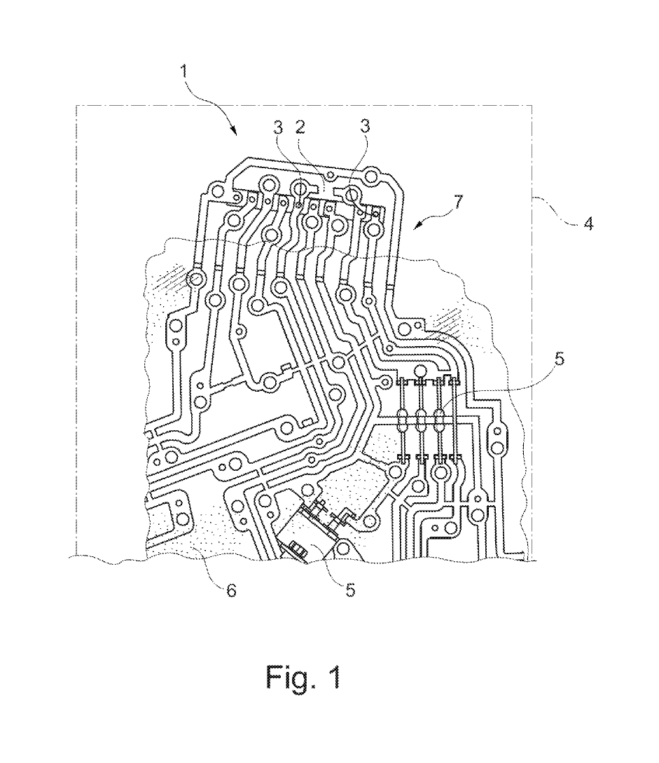

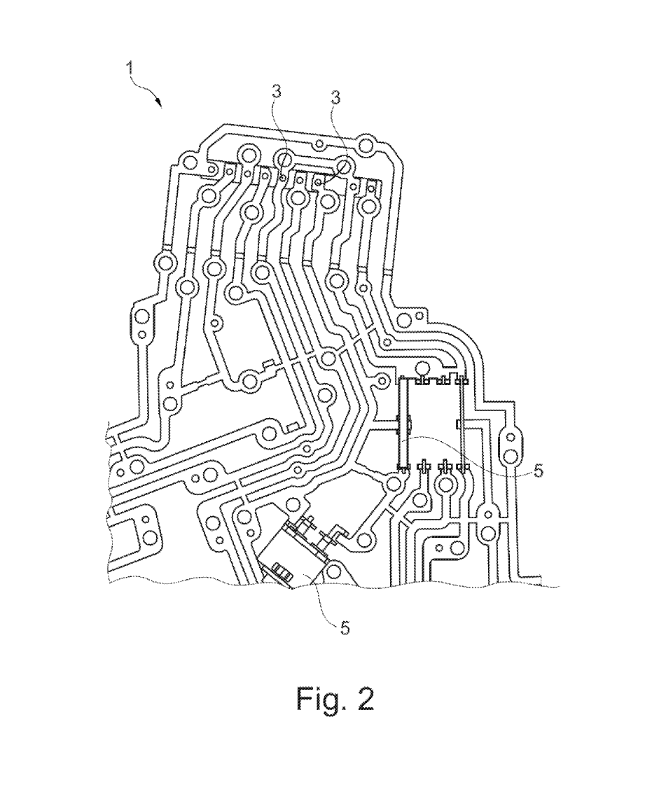

FIG. 1 shows an electric component carrier in its first variant, whilst FIG. 2 shows a variant deviating from FIG. 1 of the relevant electric component carrier.

The figures show an electric component carrier, more specifically, an electric component carrier for a lock that is suitable and intended for arrangement and attachment in a motor vehicle door lock. The relevant motor vehicle door lock is a so-called electric lock, in other words, one where a mandatory locking mechanism is usually opened mechanically. In fact, in this case, a distinction can be made between two basic variants, namely the “semi-electric” variant illustrated in FIG. 1 and the “fully electric” variant illustrated within the context of FIG. 2.

For the semi-electric mode of operation, the procedure for example is that the locking mechanism is only opened electrically, whilst the other activation elements in the motor vehicle door lock primarily operate mechanically. The fully electric variant is usually characterized in that all functional states of the motor vehicle door lock are defined by separate motors and that mechanical activation elements are provided for reasons of redundancy if need be. In any case, the individual conductive track arrangements 1 and those illustrated in FIGS. 1 and 2 in essence only differ in that starting from a conductive track arrangement 1 in the initial state, one or more separation points 2 have been introduced into the operational state depending on the desired mode of operation.

The initial state of the conductive track arrangement 1 corresponds to the respective conductive tracks of the conductive track arrangement 1 running continuously and are not equipped with the separation point 2 illustrated as an example in FIG. 1. Furthermore, possible and additionally attached contact connectors 3 are missing from the conductive track arrangement 1 in the initial state, as can be seen in the relevant FIGS. 1 and 2. The relevant contact connectors 3 are respectively attached to at least one opening of the conductive track arrangement 1 and are used for example to connect switching means. The switching means can for instance include a switch that is used to initiate a central locking system or anti-theft device. Furthermore, with the aid of the switching means it is possible to query switching states such as “Rotary latch closed” or “Internal operating lever applied”. Naturally, this is overall only an example.

The conductive track arrangement 1 is supported by a base plate 4. The base plate 4 can be a carrier plate or a supporting element that, together with the conductive track arrangement 1 and with the attached electric/electronic constructional elements 5, is accommodated and placed in a lock housing of a motor vehicle door lock which is not illustrated. In principle, the conductive track arrangement 1 including the base plate 4, which supports the conductive track arrangement 1 can also be used in a different housing, for example in an actuating drive housing to drive a sliding door, window lifter, mirror, car seat, etc. This is not depicted in detail. Furthermore, within the scope of the invention, there is the possibility that the base plate 4, which supports the conductive track arrangement 1 is formed as a component of the relevant housing, for example illustrates or can illustrate a component of the lock housing for a motor vehicle door lock.

As previously explained, the conductive track arrangement 1 serves primarily to accommodate and bond electric/electronic constructional elements 5. The conductive track arrangement 1 is therefore usually equipped at one end with a contact element, for example a plug or socket so that the electric/electronic constructional elements 5 are energized via the conductive track arrangement 1. In addition to the resistances illustrated in FIG. 1 as electronic constructional elements 5, a strip conductor bridge can also be included here, as illustrated in FIG. 2. The electric/electronic constructional elements 5 also include switches, as depicted in FIGS. 1 and 2 for both design models.

To manufacture the electric component carrier thus executed, the conductive track arrangement 1 in the initial state is initially equipped with one or several separation points 2. The initial state of the conductive track arrangement is mainly illustrated in FIG. 2, since all conductive tracks of the conductive track arrangement 1 run continuously. In contrast, with the conductive track arrangement 1, within the scope of FIG. 1, a separation point 2 is introduced and provided, which interrupts the associated conductive track.

The conductive track in detail is a conductor strip of a specified width. The material thickness of the conductor strip is usually determined by the material thickness of a sheet metal or metal film, out of which the conductive track arrangement 1 is stamped in the initial state. This means that the conductive track arrangement 1 is a leadframe in the exemplary embodiment. This is of course not restrictive.

In order to now be able to introduce the one or more separation points 2 and to prevent damage to the conductive track arrangement 1 and to the electric/electronic constructional elements 5 that are already on it or are already attached to it, the conductive track arrangement 1 in the initial state is at least partially coated with a casting compound 6, as illustrated in FIG. 1. This means that the conductive track arrangement 1 in the initial state is initially equipped with the electric/electronic constructional elements 5, at least in the region that is consequently covered by the partial coating 6. The partial coating 6 ensures that the conductive track arrangement 1 is overall stabilized since only a free region 7 is left here that is not covered by the partial coating 6. The free region 7 is much smaller in size than the whole conductive track arrangement 1, it may for example be 10% to 30% maximum of the region covered by the conductive track arrangement 1.

In a further advantageous embodiment, the conductive track arrangement is initially partially coated and then finally equipped with at least the one separation point and if necessary the contact connector, then fully coated and finally equipped with the electric/electronic constructional elements. Optionally, after placing the electric/electronic constructional elements, a liquid casting compound can be applied as a seal.

The one, or more separation points 2 can thus be introduced without problems into the relevant free region 7. For the conductive track arrangement 1 is mechanically stabilized and also protected through the partial coating 6. In order to now introduce the one, or more separation points 2, the respective separation point 2 is generally introduced into the conductive track arrangement 2 by means of a stamping/bending process. According to the exemplary embodiment, the respective separation point 2 is stamped free. For this purpose, the conductive track arrangement 1 equipped with partial coating 6 is placed in a stamping tool with one or several stamps and opposite die with the openings associated with the stamps. The stamps are mostly stamp fingers that can can be individually stamped for the stamping process. The possibility therefore exists of being able to simultaneously introduce several separation points 2 at different sites into the conductive track arrangement 1 in the free region 7. With this process, the conductive track arrangement 1 is neither damaged nor bent in any way as the partial coating 6 ensures the desired stabilization and protection of the conductive track arrangement 1.

The size and expansion of the respective stamp or stamp finger is hereby designed in such a way that the respectively separated conductor strip is completely separated over its entire width and consequently stamped free.

Thus, through the corresponding application of the individual stamps or stamp fingers, the stamping tool can be adapted to the number and position of the separation points 2 to be introduced into the conductive track arrangement 1 in the initial state and subsequently to the desired mode of operation in the finished operational state.

The conductive track arrangement 1 with the partial coating 6 and the introduced separation points 2 can now also be equipped with the one or more contact connectors 3 to connect the switching means, as illustrated in FIGS. 1 and 2. There is also the possibility to attach additional electric/electronic constructional elements 5 if necessary in the free region 7 and to connect or bond with the conductive track arrangement 1. Finally, the partially coated conductive track arrangement 1 that is also equipped with separation point 2 is then connected to the base plate 4. For this purpose and according to a preferred execution form, the conductive track arrangement 1 that has the partial coating 6 and the respective separation point 2 is fully coated with the respective casting compound as the preliminary molding with simultaneous definition of the base plate 4.

The casting compound is generally plastic and in particular thermoplastic plastic. In this instance you usually resort to one and the same plastic for both partial coating 6 and full coating, even though it is of course possible to also work with different plastics. In any case, the relevant preliminary molding is inserted into a corresponding injection molding tool and fully coated. This injection molding tool is a second injection molding tool, since the partial coating 6 was previously undertaken and executed in a first injection molding tool.

With the full coating thus executed in the second injection molding tool, the base plate 4, which supports the conductive track arrangement 1 is defined at the same time in an advantageous approach and embodiment of the invention. This means that with the aid of the plastic for the full coating, it is not only the conductive track arrangement with the separation points 2, the contact connectors 3 and the electric/electronic constructional elements 5 bonded to it, that are sealed, but this process allows the base plate 4 to be manufactured and defined at the same time. The base plate 4 can be a carrier plate or a supporting element, with the aid of which the conductive track arrangement 1 is placed into a housing. It is however also possible that the base plate 4 is a component of this housing, for example a component of the lock housing of the motor vehicle door lock. In any case, the conductive track arrangement 1 together with the electric component carrier are then in the operational state and can, in the example case, be used to control the motor vehicle door lock or to query individual components. To this end, it is only necessary for the conductive track arrangement 1 to be electrically connected to a control device in the motor vehicle via for example a connected plug or socket.

1. A method for producing an electric component carrier for automobile applications, in particular an electric component carrier for a lock, with a conductive track arrangement and a base plate which supports the conductive track arrangement, whereby the conductive track arrangement in the initial state has one or more separation points depending upon the required mode of operation in the operational state, wherein the conductive track arrangement in the initial state is at least partially coated with a casting compound, in particular plastic, and that the separation point is then introduced into the free region.

2. The method according to claim 1, wherein the partially coated conductive track arrangement that is also equipped with the separation point is then connected to the base plate.

3. The method according to claim 1, wherein the partially coated conductive track arrangement that is also equipped with the separation point is fully coated with the casting compound as the preliminary molding, preferably with simultaneous definition of the base plate.

4. The method according to claim 1, wherein the conductive track arrangement in the initial state is stamped out of a sheet metal or metal film.

5. The method according to claim 1, wherein the respective separation point is introduced into the conductive track arrangement by means of a stamping/bending process.

6. The method according to claim 5, wherein the respective separation point (2) is stamped free.

7. The method according to claim 1, wherein the conductive track arrangement, depending on the mode of operation, is equipped with at least one contact connector in addition to the separation point, that has been introduced into an opening to connect switching means for example.

8. The method according to claim 1, wherein the conductive track arrangement is initially equipped with the electrical/electronic constructional elements and then partially coated, and then finally equipped with at least the one separation point and if necessary the contact connector and optional additional electric/electronic constructional elements, and then finally fully coated.

9. The method according to claim 1, wherein the conductive track arrangement is initially partially coated and then finally equipped with at least the one separation point and if necessary the contact connector, then fully coated and finally equipped with the electric/electronic constructional elements.

10. The method according to claim 1, wherein the conductive track arrangement is initially partially coated in a first injection molding tool and then finally fully coated in another second injection molding tool.

11. An electric component carrier for automobile applications, in particular an electric component carrier, preferably manufactured with recourse to the process according to claim 1, with a conductive track arrangement equipped with electric/electronic constructional elements, and with a base plate which supports the conductive track arrangement, whereby the conductive track arrangement in an initial state has at least one introduced separation point depending upon the required mode of operation in the operational state, wherein the separation point is introduced into a free region of the conductive track arrangement that in the initial state is at least partially coated with casting compound.
